(19) United States
(12) Patent Application Publication
(10) Pub. No.: US 2026/0277094 A1
(43) Pub. Date: Sep. 17, 2026

(54) REFLECTIVE MASK BLANK, REFELCTIVE MASK, AND METHOD FOR PRODUCING REFLECTIVE MASK

(71) Applicant: AGC INC., Tokyo (JP)

(72) Inventors: Ryosuke SEI, Tokyo (JP); Shingo URATA, Tokyo (JP)

(73) Assignee: AGC INC., Tokyo (JP)

(21) Appl. No.: 19/675,553

(22) Filed: May 13, 2026

Related U.S. Application Data
(63) Continuation of application No. PCT/JP2024/036843, filed on Oct. 16, 2024.

(30) Foreign Application Priority Data
Nov. 27, 2023 (JP) 2023-199954

(51) Int. Cl. G03F 1/26; G03F 1/24

(52) U.S. Cl. CPC G03F 1/26; G03F 1/24

(57) ABSTRACT

Provided is a reflective mask blank containing Pt and having low crystallinity. The reflective mask blank includes, in the following order, a substrate, a multilayer reflective film configured to reflect EUV light, a protective film and a phase shift film configured to cause a phase shift in EUV light, wherein the phase shift film contains Pt and at least one first element X1 selected from the group consisting of Cr, Hf, Ta and W, wherein the content of the first element X1 in the phase shift film is 10.0 atomic % or more and less than 70.0 atomic % relative to all atoms in the phase shift film, and wherein when the phase shift film is analyzed by X-ray photoelectron spectroscopy, the chemical shift of the Pt 4f_{7/2} peak is 0.3 eV or more.

This application is a continuation of International Application No. PCT/JP2024/036843, filed on Oct. 16, 2024, which claims the benefit of priority to Japanese Application No. 2023-199954, filed Nov. 27, 2023; the disclosure of each of these applications are each incorporated herein by reference in their entirety.

### TECHNICAL FIELD

The present invention relates to a reflective mask used for EUV (Extreme Ultra Violet) exposure in a semiconductor manufacturing exposure process, a method for producing the reflective mask, and a reflective mask blank that serves as an original plate for the reflective mask.

### BACKGROUND ART

Recent years have seen studies of EUV lithography, which uses EUV light with a center wavelength of approximately 13.5 nm as a light source, for further miniaturization of semiconductor devices.

In EUV exposure, a reflective optical system and a reflective mask are used due to the characteristics of EUV light. The reflective mask has a multilayer reflective film provided on a substrate to reflect EUV light and a patterned absorber film provided on the multilayer reflective film to absorb EUV light.

EUV light incident on the reflective mask from an illumination optical system of the exposure equipment is reflected at areas (opening areas) where the absorber film is not present and is absorbed at areas (non-opening areas) where the absorber film is present. By projecting the reflected light onto a resist on a wafer through a reduction projection optical system of the exposure equipment, the mask pattern is transferred to the resist. The resulting resist pattern is then subjected to subsequent processes.

The absorber film may be in the form of a so-called phase shift film that causes a phase shift in EUV light to reduce the reflectivity of EUV light. In the phase shift film, the reflectivity of EUV light is reduced by interference between EUV light reflected from a surface of the absorber film opposite to the multilayer reflective film and EUV light reflected from a surface of the absorber film facing the multilayer reflective film.

As an example of such a phase shift film, Patent Document 1 discloses a phase shift film that contains platinum (Pt) in view of optical properties, and more specifically discloses an absorber film (phase shift film) formed using Pt.

### PRIOR ART DOCUMENTS

### Patent Documents

Patent Document 1: WO2022/065421

### DISCLOSURE OF INVENTION

### Technical Problem

For phase shift films of reflective mask blanks, low crystallinity is required to suppress variations in line width during patterning, in addition to the optical properties of the constituent materials.

The present inventors have examined the Pt-containing phase shift film disclosed in Patent Document 1 and found that the disclosed phase shift film exhibits high crystallinity. Accordingly, there has been a desire to reduce the crystallinity of the phase shift film.

The present invention has been made in view of the above-described problem. It is an object of the present invention to provide a reflective mask blank containing Pt and having low crystallinity.

It is also an object of the present invention to provide a reflective mask and a method for producing a reflective mask.

### Solution to Problem

As a result of intensive studies on the above-described problem, the present inventors have found that the above-described problem can be solved by containing a specific metal element and a specific amount of a specific light element, and have thus accomplished the present invention.

Namely, the present inventors have found the following solutions to the above-described problem.
[1] A reflective mask blank comprising, in the following order:
   a substrate;
   a multilayer reflective film configured to reflect EUV light;
   a protective film; and
   a phase shift film configured to cause a phase shift in EUV light,
   wherein the phase shift film comprises:
   Pt; and
   at least one first element X1 selected from the group consisting of Cr, Hf, Ta and W,
   wherein the content of the first element X1 in the phase shift film is 10.0 atomic % or more and less than 70.0 atomic % relative to all atoms in the phase shift film, and
   wherein the phase shift film, when analyzed by X-ray photoelectron spectroscopy, shows a peak corresponding to a Pt 4f_{7/2} orbital, the peak having a chemical shift of 0.3 eV or more.
[2] The reflective mask blank according to [1], wherein the content of Pt in the phase shift film is 30.0 atomic % or more and less than 90.0 atomic % relative to all atoms in the phase shift film.
[3] The reflective mask blank according to [1] or [2],
   wherein the first element X1 includes at least Ta, and
   wherein the content of Ta in the phase shift film is 10.0 atomic % or more and less than 70.0 atomic % relative to all atoms in the phase shift film.
[4] The reflective mask blank according to [1] or [2], wherein the first element X1 includes at least W, and wherein the content of W in the phase shift film is 10.0 to 40.0 atomic % relative to all atoms in the phase shift film.
[5] The reflective mask blank according to [1] or [2],
   wherein the first element X1 includes at least Hf, and
   wherein the content of Hf in the phase shift film is 10.0 to 60.0 atomic % relative to all atoms in the phase shift film.
[6] The reflective mask blank according to any one of [1] to [5], wherein the phase shift film has a refractive index n of 0.910 or higher.
[7] The reflective mask blank according to any one of [1] to [6], wherein the phase shift film has an extinction coefficient of lower than 0.050.
[8] The reflective mask blank according to any one of [1] to [7], wherein the phase shift film is amorphous.
[9] The reflective mask blank according to any one of [1] to [8], wherein the phase shift film has a film thickness of 10 to 60 nm.
[10] The reflective mask blank according to any one of [1] to [9], wherein the protective film comprises at least one element selected from the group consisting of Si, Y, Ru, Rh, Pd and Al.
[11] The reflective mask blank according to any one of [1] to [10], further comprising an etching mask film, different from the phase shift film, on a side of the phase shift film opposite to the substrate,
   wherein the etching mask film comprises at least one element selected from the group consisting of Al, Si, Ti, Cr, Y, Nb, Mo, Ta and Hf.
[12] The reflective mask blank according to [11], wherein the etching mask film further comprises at least one element selected from the group consisting of B, C, N, O and F.
[13] A reflective mask comprising a phase shift film pattern formed by patterning the phase shift film of the reflective mask blank according to any one of [1] to [12].
[14] A method for producing a reflective mask, comprising patterning the phase shift film of the reflective mask blank according to any one of [1] to [12].

### Advantageous Effects of Invention

According to the present invention, it is possible to provide a reflective mask blank containing Pt and having low crystallinity.

According to the present invention, it is also possible to provide a reflective mask and a method for producing a reflective mask.

### BRIEF DESCRIPTION OF DRAWINGS

FIG. 1 is a schematic view illustrating an example embodiment of the reflective mask blank of the present invention.

FIGS. 2A to 2D are schematic views illustrating an example of a method for producing a reflective mask using the reflective mask blank of the present invention.

### DESCRIPTION OF EMBODIMENTS

Hereinafter, the present invention will be described in detail.

Although the features of the present invention will sometimes be described based on typical embodiments of the present invention, the present invention is not limited to these embodiments.

The following expressions used in the present specification have the following meanings.

In the present specification, a numerical range expressed using “to” indicates a range including numerical values described before and after “to” as the lower and upper limits.

In the present specification, elements such as boron, carbon, nitrogen, oxygen, aluminum, silicon, titanium, chromium, yttrium, zirconium, niobium, molybdenum, ruthenium, rhodium, palladium, tantalum, tungsten, hafnium, rhenium, iridium and platinum may be respectively expressed by their corresponding chemical symbols (such as B, C, N, O, Al, Si, Ti, Cr, Y, Zr, Nb, Mo, Ru, Rh, Pd, Ta, W, Hf, Re, Ir and Pt).

### <Reflective Mask Blank>

The reflective mask blank of the present invention includes, in the following order, a substrate, a multilayer reflective film configured to reflect EUV light, a protective film, and a phase shift film configured to cause a phase shift in EUV light.

In the reflective mask blank of the present invention, the phase shift film contains: Pt; and at least one first element X1 selected from the group consisting of Cr, Hf, Ta and W. Here, the content of the first element X1 in the phase shift film is 10.0 atomic % or more and less than 70.0 atomic % relative to all atoms in the phase shift film.

Furthermore, when the phase shift film in the reflective mask blank of the present invention is analyzed by X-ray photoelectron spectroscopy, the chemical shift of the peak corresponding to the Pt 4f_{7/2} orbital is 0.3 eV or more.

The reflective mask blank of the present invention will be described below with reference to the drawings.

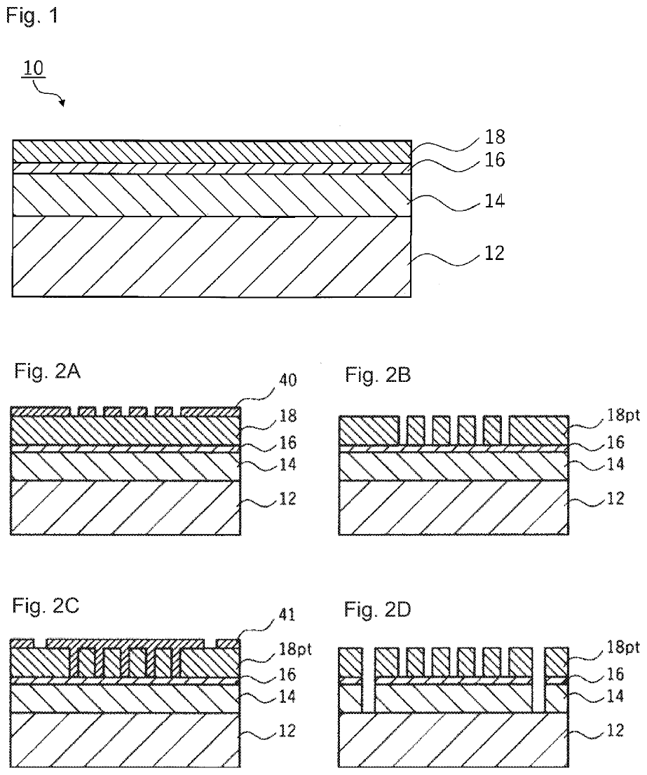

FIG. 1 is a cross-sectional view illustrating an example embodiment of the reflective mask blank of the present invention. A reflective mask blank 10 shown in FIG. 1 includes a substrate 12, a multilayer reflective film 14, a protective film 16 and a phase shift film 18 arranged in this order.

The phase shift film 18 contains Pt and the first element X1, wherein: the content of the first element X1 is within the predetermined range; and the chemical shift of Pt is 0.3 eV or more.

Further, the reflective mask blank 10 may include an etching mask film on a side of the phase shift film 18 opposite to the substrate 12 as will be described later.

The mechanism by which the phase shift film in the reflective mask blank of the present invention exhibits low crystallinity is not entirely clear, but is presumed by the present inventors as follows.

In the reflective mask blank of the present invention, the phase shift film can be readily reduced in crystallinity by containing Pt together with a predetermined amount of the first element X1.

Furthermore, the phase shift film in the reflective mask blank of the present invention shows a Pt 4f_{7/2} peak with a chemical shift of 0.3 eV or more. When the chemical shift of Pt is within the above range, it indicates that Pt is influenced by the first element X1, corresponding to the presence of a large number of X1 atoms around Pt. This results in a lower proportion of Pt atoms adjacent to other Pt atoms, which in turn leads to a further reduction in crystallinity.

First, the respective components of the reflective mask blank of the present invention will be described below.

### [Substrate]

The substrate in the reflective mask blank of the present invention preferably has a low thermal expansion coefficient. When the thermal expansion coefficient of the substrate is low, it is possible to suppress distortion in the pattern of the phase shift film due to heat during exposure to EUV light.

The thermal expansion coefficient of the substrate at 20° C. is preferably 0±1.0×10⁻⁷/° C., more preferably 0+0.3×10⁻⁷/° C.

As the substrate material with a low thermal expansion coefficient, SiO₂—TiO₂ glass may be mentioned. The substrate material is however not limited to this glass. Substrates made of crystallized glass with β-quartz solid solution precipitated therein, quartz glass, metallic silicon, metals and the like can also be used.

The SiO₂—TiO₂ glass is preferably quartz glass having a SiO₂ content of 90 to 95 mass % and a TiO₂ content of 5 to 10 mass %. When the TiO₂ content is 5 to 10 mass %, the linear expansion coefficient of the glass is substantially zero at around room temperature so that the glass causes almost no dimensional change at around room temperature. The SiO₂—TiO₂ glass may contain any trace component other than SiO₂ and TiO₂.

Preferably, a surface of the substrate on which the multilayer reflective film is arranged (hereinafter also referred to as the “first main surface”) has high surface smoothness. The surface smoothness of the first main surface can be evaluated on the basis of surface roughness. The surface roughness of the first main surface is preferably 0.15 nm or less in terms of the root mean square roughness Rq. Here, the surface roughness can be measured with an atomic force microscope, and will be described as the root mean square roughness Rq according to JIS B0601.

For improvements in pattern transfer accuracy and positional accuracy of a reflective mask obtained from the reflective mask blank, the first main surface is preferably processed to a certain level of flatness. The flatness of the substrate in a predetermined region (for example, a 132 mm×132 mm region) of the first main surface is preferably 100 nm or less, more preferably 50 nm or less, still more preferably nm or less. The flatness can be measured with a flatness meter manufactured by FUJINON Corporation.

The size and thickness of the substrate are determined as appropriate depending on the mask design value and the like. For example, the substrate may have an outer shape of 6 inches (152 mm) square and a thickness of 0.25 inches (6.3 mm).

The substrate is often rectangular or square in shape.

The substrate preferably has high rigidity to prevent distortion caused due to stresses of the films (such as multilayer reflective film, protective film and phase shift film) formed thereon. For example, the substrate preferably has a Young's modulus of 65 GPa or higher.

### [Multilayer Reflective Film]

The multilayer reflective film in the reflective mask blank of the present invention is not particularly limited, so far as it has properties desired for reflective films of EUV mask blanks. The multilayer reflective film preferably has high reflectance for EUV light. More specifically, when a surface of the multilayer reflective film is irradiated with EUV light at an incident angle of 6°, the maximum value of the reflectance for EUV light with wavelengths of around 13.5 nm is preferably 60% or higher, more preferably 65% or higher. Even when the protective film is arranged on the multilayer reflective film, the maximum value of the reflectance for EUV light with wavelengths of around 13.5 nm is preferably 60% or higher, more preferably 65% or higher.

To achieve high EUV light reflectance, the multilayer reflective film is generally one in which high-refractive-index layers with a high refractive index to EUV light and low-refractive-index layers with a low refractive index to EUV light are alternately stacked multiple times.

The multilayer reflective film may have a multilayer structure formed from a plurality of units, provided that each unit includes a high-refractive-index layer and a low-refractive-index layer stacked in this order from the substrate side. The multilayer reflective film may have a multilayer structure formed from a plurality of units, provided that each unit includes a low-refractive-index layer and a high-refractive-index layer stacked in this order from the substrate side.

The high-refractive-index layers may be layers containing Si. Examples of the Si-containing material include elemental Si, and Si compounds containing Si and at least one selected from the group consisting of B, C, N and O. With the use of such Si-containing high-refractive-index layers, a reflective mask with high EUV light reflectance can be obtained.

The low-refractive-index layers can be layers containing a metal selected from the group consisting of Mo, Ru, Rh and Pt or an alloy thereof.

It is common to use Si in the high-refractive-index layers and use Mo in the low-refractive-index layers. In other words, a Mo/Si multilayer reflective film is most commonly used. The multilayer reflective film is however not limited to this type. The multilayer reflective film may be of any other type, such as a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film, a Si/Ru/Mo multilayer reflective film or a Si/Ru/Mo/Ru multilayer reflective film.

The thickness of each layer and the number of repetitions of layer units in the multilayer reflective film are selected as appropriate depending on the film materials used and the EUV light reflectance required of the reflective film. For example, a Mo/Si multilayer reflective film with a maximum EUV light reflectance of 60% or higher can be obtained when Mo layers with a thickness of 2.3+0.1 nm and Si layers with a thickness of 4.5+0.1 nm are alternately stacked such that the number of repetitions of these layer units ranges from 30 to 60.

Each of the layers of the multilayer reflective film can be formed with a desired thickness by a known film formation method such as magnetron sputtering, ion beam sputtering method or the like. For example, the multilayer reflective film can be formed by ion beam sputtering in which ion particles from an ion source are supplied onto targets of high- and low-refractive-index materials. In the case of a Mo/Si multilayer reflective film, for example, a Si layer of predetermined thickness is first formed on the substrate by ion beam sputtering using a Si target, and then, a Mo layer of predetermined thickness is formed by ion beam sputtering using a Mo target. Assuming such stacking of Si and Mo layers as one cycle, the Mo/Si multilayer reflective film is obtained by 30 to 60 repetitions of this stacking cycle.

### [Protective Film]

In the reflective mask blank of the present invention, the protective film is provided between the multilayer reflective film and the phase shift film. The protective film serves to, during patterning of the phase shift film by an etching process (in general, a dry etching process), protect the multilayer reflective film from damage by the etching process.

The protective film is preferably made of a material containing at least one element selected from the group consisting of Si, Y, Ru, Rh, Pd and Al, more preferably a material containing at least one element selected from the group consisting of Ru and Rh.

Examples of the Si-containing material include Si oxides, Si nitrides, Si oxynitrides, and alloys containing Si.

Examples of the Y-containing material include Y oxides, Y fluorides, Y oxyfluorides, and alloys containing Y.

Examples of the Ru-containing material include elemental Ru, and Ru alloys containing Ru and at least one metal selected from the group consisting of Si, Ti, Nb, Rh and Zr.

Examples of the Rh-containing material include elemental Rh, Rh alloys containing Rh and at least one metal selected from the group consisting of Si, Ti, Nb, Ru, Ta and Zr, Rh-containing nitrides containing the aforementioned Rh alloys and nitrogen, and Rh-containing oxynitrides containing the aforementioned Rh alloys, nitrogen and oxygen.

Examples of the Pd-containing material include elemental Pd, and Pd alloys containing Pd and at least one metal selected from the group consisting of Si, Ti, Zr, Nb, Ru, Rh and Ta.

As the material capable of achieving the above purpose, Al, nitrides containing these metals and nitrogen, and Al₂O₃ may also be mentioned.

Among others, elemental Ru, a Ru alloy, elemental Rh or a Rh alloy is preferred as the material to achieve the above purpose. As the Ru alloy, a Ru—Si alloy is preferred. As the Rh alloy, a Rh—Si alloy is preferred.

The film thickness of the protective film is not particularly limited, so far as the protective film performs its function. To maintain the EUV light reflectivity of the multilayer reflective film, the film thickness of the protective film is preferably 1 to 10 nm, more preferably 1.5 to 6 nm, still more preferably 2 to 5 nm.

It is a preferred embodiment that elemental Ru, a Ru alloy, elemental Rh or a Rh alloy is used as the material of the protective film and that the film thickness of the protective film is within the above-mentioned preferable thickness range.

The protective film may be a single-layer film or a multilayer film formed from a plurality of layers. In the case where the protective film is a multilayer film, each of the layers in the multilayer film is preferably made of the above preferable material. In the case where the protective film is a multilayer film, the total thickness of the layers in the multilayer film is preferably within the above-mentioned preferable thickness range.

The protective film can be formed by a known film formation method such as magnetron sputtering, ion beam sputtering or the like. In the case where a Ru film is formed by magnetron sputtering, the sputtering is preferably performed using a Ru target as the target and Ar gas as the sputtering gas.

### [Phase Shift Film]

The phase shift film in the reflective mask blank of the present invention contains Pt and at least one first element X1 selected from the group consisting of Cr, Hf, Ta and W. Here, the content of the first element X1 in the phase shift film is 10 atomic % or more and less than 70 atomic % relative to all atoms in the phase shift film.

Further, when the phase shift film in the reflective mask blank of the present invention is analyzed by X-ray photoelectron spectroscopy, the chemical shift of the Pt 4f_{7/2} peak is 0.3 eV or more.

The phase shift film will now be described in detail.

The content of the first element X1 in the phase shift film is 10.0 atomic % or more and less than 70.0 atomic % relative to all atoms in the phase shift film. The content of the first element X1 in the phase shift film is preferably 15.0 to 65.0 atomic %, more preferably 20.0 to 60.0 atomic %, still more preferably 30.0 to 50.0 atomic %, particularly preferably 40.0 to 50.0 atomic %, relative to all atoms in the phase shift film. The content of the first element X1 in the phase shift film is determined by analysis using X-ray photoelectron spectroscopy (XPS). The detailed analysis conditions will be described later.

The first element X1 is at least one element selected from the group consisting of Cr, Hf, Ta and W, and is preferably at least one element selected from the group consisting of Hf, Ta and W.

The phase shift film may contain a single first element X1 or two or more first elements X1. In the case where the phase shift film contains two or more first elements X1, the content of the first element X1 refers to the total content of the first elements X1.

In the case where the first element X1 includes at least Ta, the content of Ta relative to all atoms in the phase shift film is preferably 10.0 atomic % or more and less than 70.0 atomic %, more preferably 20.0 to 60.0 atomic %, still more preferably 30.0 to 50.0 atomic %, particularly preferably 33.0 to 45.0 atomic %, so as to achieve superior optical properties for EUV light and lower crystallinity.

In the case where the first element X1 includes at least W, the content of W relative to all atoms in the phase shift film is preferably 5.0 to 60.0 atomic %, more preferably 10.0 to 40.0 atomic %, still more preferably 11.0 to 20.0 atomic %, particularly preferably 11.0 to 15.0 atomic %, so as to achieve superior optical properties for EUV light and lower crystallinity.

In the case where the first element X1 includes at least Hf, the content of Hf relative to all atoms in the phase shift film is preferably 5.0 atomic % or more and less than 70.0 atomic %, more preferably 10.0 to 60.0 atomic %, still more preferably 15.0 to 40.0 atomic %, so as to achieve superior optical properties for EUV light and lower crystallinity.

The content of Pt in the phase shift film is preferably 30.0 atomic % or more, more preferably 40.0 atomic % or more, still more preferably 50.0 atomic % or more, relative to all atoms in the phase shift film. The upper limit of the content of Pt in the phase shift film is preferably less than 90.0 atomic %, more preferably 80.0 atomic % or less, still more preferably 70.0 atomic % or less, particularly preferably 60.0 atomic % or less, relative to all atoms in the phase shift film.

The content of Pt in the phase shift film is determined by analysis using XPS. The detailed analysis method will be described later.

Further, when the phase shift film is analyzed by XPS, the chemical shift of the Pt 4f_{7/2} peak is 0.3 eV or more. The chemical shift may be 0.4 eV or more, may be 0.5 eV or more, or may be 0.7 eV or more. The upper limit of the chemical shift is not particularly limited, but it is often 1.5 eV or less, and more frequently 1.2 eV or less. In the following, the XPS analysis in the present specification will be described.

The XPS analysis is conducted using an analysis instrument “PHI 5000 VersaProbe” manufactured by ULVAC-PHI, Inc. This instrument is calibrated in accordance with JIS K0145.

First, a measurement sample is prepared by cutting a reflective mask blank into an approximately 1 cm square. The prepared measurement sample is set in a measurement holder such that the phase shift film side of the sample serves as a measurement surface.

The measurement holder is placed in the analysis instrument, and a 5-nm outer surface layer of the phase shift film is removed by sputtering with an argon ion beam. In the case where the phase shift film is not exposed, the sputtering is performed until the phase shift film becomes exposed, after which an additional 5-nm layer of the phase shift film is removed from the exposed outer surface. The sputtering rate during this operation can be measured using a separately prepared sample.

After removing the outer surface layer of the phase shift film, the analysis is carried out by irradiating the exposed area of the phase shift film with X-rays (monochromatic AlK_{α} radiation) at a photoelectron take-off angle of 45° (the angle between the measurement sample surface and the detector). During the analysis, charging is suppressed using a neutralizer gun.

In the analysis, a wide scan is first performed over the binding energy range of 1,000 to 0 eV to detect the elements present. Subsequently, a narrow scan is performed for the detected elements (such as Pt and the first element X1). The narrow scan is performed, for example, with a pass energy of 58.7 eV, an energy step of 0.1 eV, a time per step of 50 ms and a total of 10 scans. The wide scan is performed, for example, with a pass energy of 58.7 eV, an energy step of 1 eV, a time per step of 50 ms and a total of 2 scans.

Here, the binding energy calibration is carried out using the C 1s peak of carbon originating from the measurement sample. More specifically, before removing a 5-nm outer surface layer of the phase shift film by sputtering with an argon ion beam, the binding energy of the C 1s peak of the measurement sample is determined from the narrow scan analysis. A shift value is then calculated by subtracting this binding energy value from 284.8 eV. The calculated shift value is added to the binding energy of each elemental orbital peak, determined from the narrow scan analysis, to obtain the calibrated binding energy of each elemental orbital peak. The chemical shift of each peak refers to a deviation from the literature value. In the present specification, 71.1 eV is employed as the value for the Pt 4f_{7/2} peak. In the present specification, chemical shifts toward the higher binding energy side are expressed as positive values, and chemical shifts toward the low binding energy side are expressed as negative values.

In the case where the phase shift film contains C as a constituent component, the binding energy calibration is carried out using Au with its surface cleaned under ultrahigh vacuum. In this case, the shift value is calculated by determining the binding energy of the Au 4f_{7/2} orbital from the narrow scan analysis and subtracting this determined value from 83.96 eV.

When the binding energy of each orbital peak is determined from the narrow scan analysis, the peak top value is employed as the binding energy value.

The contents of Pt and the first element X1 are determined from the narrow-scan spectra obtained by the above XPS analysis procedure with reference to the relative sensitivity factors specific to each element and orbital.

The absolute value of the chemical shift of the first element X1 is preferably 0.1 eV or more, more preferably 0.2 eV or more, still more preferably 0.3 eV or more. The chemical shift may be 0.5 eV or more, may be 0.8 eV or more, may be 1.0 eV or more, or may be 1.5 eV or more. The upper limit of the chemical shift is not particularly limited and is often, for example, 2.0 eV or less.

The chemical shift of the first element X1 is determined in the same manner as that of the Pt 4f_{7/2} peak. In the case where Cr is included as the first element X1, the analysis is performed on the 2p orbital. In the case where Hf, Ta or W is included as the first element X1, the analysis is performed on the 4f orbital. The detailed determination method will be described in the Examples below.

The phase shift film may contain an additional element other than Pt and the first element X1. The additional element may be at least one element selected from the group consisting of B, C, N, O and Si.

In the phase shift film, one type of additional element may be contained, or two or more types of additional elements may be contained.

In the case where the phase shift film contains an additional element, the content of the additional element is preferably more than 0.0 atomic % and 10.0 atomic % or less, more preferably more than 0.0 atomic % and 5.0 atomic % or less, relative to all atoms in the phase shift film.

The phase shift film may preferably contain no additional element. In other words, the phase shift film may preferably consist of Pt and the first element X1.

The refractive index n of the phase shift film is preferably 0.900 or higher, more preferably 0.910 or higher. The refractive index n of the phase shift film is preferably 0.950 or lower, more preferably 0.940 or lower, still more preferably 0.930 or lower, particularly preferably 0.920 or lower, so as to reduce the film thickness of the phase shift film.

The extinction coefficient k of the phase shift film is preferably lower than 0.060, more preferably lower than 0.050, still more preferably 0.048 or lower. The extinction coefficient k of the phase shift film is preferably 0.035 or higher, more preferably 0.040 or higher, still more preferably 0.042 or higher, so as to facilitate adjustment of the reflectance of the phase shift film to a lower value.

The refractive index n and the extinction coefficient k are determined by measuring the incidence-angle dependence of the reflectance for EUV light with a wavelength of 13.5 nm and fitting the measured profile with n and k as parameters.

The EUV light reflectance of the phase shift film is preferably 2% or higher. To obtain a sufficient phase shift effect, the reflectance of the phase shift film is more preferably 9 to 15%.

The phase shift film in the reflective mask blank of the present invention exhibits low crystallinity. Here, “low crystallinity” of the phase shift film refers to a small crystallite size determined from an X-ray diffraction (XRD) chart. The crystallite size is calculated by the Scherrer equation. For the calculation of the crystallite size by the Scherrer equation, the full width at half maximum of the highest-intensity diffraction peak in the 2θ range of 30° to 55° is used. In the case where no distinct diffraction peak is observed in the diffraction chart, the phase shift film can be considered amorphous.

In the present invention, the crystallite size of the phase shift film is preferably 10.0 nm or smaller, more preferably 6.0 nm or smaller, still more preferably 4.0 nm or smaller. The lower limit of the crystallite size is not particularly limited, and is often 0.1 nm or greater. In the present invention, the phase shift film may be amorphous.

The film thickness of the phase shift film is preferably 10 to 60 nm, more preferably 20 to 60 nm. The film thickness of the phase shift film is determined by X-ray reflectivity.

Preferably, the phase shift film is resistant to dissolution in a cleaning liquid. When the phase shift film is resistant to dissolution in a cleaning liquid, it is less likely that the phase shift film will be removed during an etching process of an etching mask film as will be described later, thereby facilitating formation of a desired pattern. More specifically, it is preferable that the phase shift film shows a small change in film thickness when brought into contact with a sulfuric acid-hydrogen peroxide mixture (SPM).

For example, when an etching process is performed using SPM at 100° C. for 20 minutes, the change in film thickness of the phase shift film before and after the etching process is preferably 1.0 nm or less, more preferably 0.5 nm or less, still more preferably 0.2 nm or less.

Specific conditions for the etching process are in accordance with those described in the Examples below.

To improve the dissolution resistance of the phase shift film to a cleaning liquid, the phase shift film preferably contains Ta as the first element X1. In this case, the content of Ta in the phase shift film may be within the above-mentioned preferable content range.

The phase shift film can be formed by a known film formation method such as magnetron sputtering, ion beam sputtering or the like. For example, in the case where a PtTa film is formed as the phase shift film by magnetron sputtering, the sputtering can be performed using Pt and Ta targets while supplying Ar-containing gas.

A target of Pt—Ta alloy (a PtTa target) may be used as a sputtering target to form a PtTa film. That is, an alloy target containing Pt and the first element X1 may be used.

### [Etching Mask Film]

The reflective mask blank of the present invention may include an etching mask film on a side of the phase shift film opposite to the substrate.

The etching mask film is preferably made of a material having high resistance to dry etching. By forming the etching mask film on the phase shift film, dry etching can be performed even when the minimum line width of the phase shift film pattern is reduced. Accordingly, the formation of the etching mask film is effective for the miniaturization of the phase shift film pattern.

The etching mask film preferably contains at least one element (hereinafter also referred to as “third element X3”) selected from the group consisting of Al, Si, Ti, Cr, Y, Nb, Mo, Ta and Hf. In other words, the constituent material of the etching mask film preferably contains a third element X3.

The etching mask film preferably further contains at least one element selected from the group consisting of B, C, N, O and F.

As the constituent material of the etching mask film, for example, an elemental form of the third element X3, and borides, oxides, nitrides, oxynitrides, carbides, carbonitrides, oxycarbides, fluorides and oxyfluorides of the third element X3 may be mentioned. The constituent material of the etching mask film may be a compound (such as a composite oxide) containing two or more third elements X3.

Examples of the Cr-based materials containing Cr as the third element X3 include Cr and materials containing Cr together with one or more elements selected from the group consisting of O, N, C and H. More specifically, CrO, CrN and CrON may be mentioned. Here, “CrON” refers to a material containing Cr, O and N; and the same applies to similar expressions used below.

Examples of the Si-based materials containing Si as the third element X3 include Si and materials containing Si together with one or more elements selected from the group consisting of O, N, C and H. More specifically, SiO₂, SION, SIN, SiO, Si, SiC, SiCO, SiCN and SiCON may be mentioned.

### [Conductive Film]

The reflective mask blank of the present invention may include a conductive film on a surface (second main surface) of the substrate opposite to the first main surface. The reflective mask blank, when provided with a conductive film, can be handled using an electrostatic chuck.

The conductive film preferably has a low sheet resistance. For example, the sheet resistance of the conductive film is preferably 200 Q/sq. or less, more preferably 100 Q/sq. or less.

The constituent material of the conductive film can be selected from a wide range of materials disclosed in the known literature. For example, the conductive film may be a high-dielectric coating described in JP-A-2003-501823, such as a coating composed of Si, Mo, Cr, CrON or TaSi. Alternatively, the conductive film may be made of a Cr compound containing Cr and one or more elements selected from the group consisting of B, N, O and C, or a Ta compound containing Ta and one or more elements selected from the group consisting of B, N, O and C.

The thickness of the conductive film is preferably 10 to 1,000 nm, more preferably to 400 nm.

The conductive film may have the function of stress adjustment on the second main surface side of the reflective mask blank. In other words, the conductive film can adjust a balance with stresses from the films formed on the first main surface side, thereby flattening the reflective mask blank.

The conductive film can be formed by a known film formation method such as a sputtering method e.g. magnetron sputtering, ion beam sputtering or the like, a CVD method, a vacuum evaporation method or an electroplating method.

### [Other Film]

The reflective mask blank of the present invention may include any other film.

The other film may be, for example, an anti-reflection film used for inspection of absorber film pattern by irradiation with inspection light (e.g. light with a wavelength of 193 to 248 nm). The anti-reflection film is preferably disposed on the side of the phase shift film opposite to the substrate.

### <Method for Producing Reflective Mask and Reflective Mask>

A reflective mask is obtained by patterning the phase shift film of the reflective mask blank of the present invention. An example of a method for producing a reflective mask will be described below with reference to FIGS. 2A to 2D.

FIG. 2A shows a state in which a resist pattern 40 is formed on a reflective mask blank having, in order, a substrate 12, a multilayer reflective film 14, a protective film 16 and a phase shift film 18. The resist pattern 40 can be formed by a known method. For example, the resist pattern 40 is formed by applying a resist onto the phase shift film 18 of the reflective mask blank, followed by exposing and developing the resist. The resist pattern 40 corresponds to a pattern to be formed on a wafer using a reflective mask.

Subsequently, the phase shift film 18 is patterned by etching using the resist pattern 40 of FIG. 2A as a mask, and then the resist pattern 40 is removed. As a result, a laminate having a phase shift film pattern 18pt as shown in FIG. 2B is obtained.

As shown in FIG. 2C, a resist pattern 41 is formed on the laminate of FIG. 2B corresponding to the frame of the exposure region. Using the resist pattern 41 of FIG. 2C as a mask, dry etching is performed until reaching the substrate 12. After the dry etching, the resist pattern 41 is removed, thereby obtaining a reflective mask as shown in FIG. 2D.

The dry etching for forming the phase shift film pattern 18pt can be performed, for example, using a CI-based gas or a F-based gas.

The resist pattern 40 or 41 can be removed by a known method, for example, by using a cleaning liquid. Examples of the cleaning liquid include a sulfuric acid-hydrogen peroxide mixture (SPM), sulfuric acid, aqueous ammonia, an ammonia-hydrogen peroxide mixture (APM), an OH radical-containing cleaning solution and ozone water.

In the case where the reflective mask blank has an etching mask film as an additional film, the etching mask film may be patterned using the resist pattern 40 as a mask, and then, the dry etching may be performed using the resulting etching mask film pattern as a mask. In the case where the reflective mask blank has an etching mask film as an additional film, the etching mask film may be removed during the process of producing the reflective mask. Furthermore, the etching mask film may be removed simultaneously with the removal of the resist pattern 40 or 41.

The reflective mask obtained by patterning the phase shift film of the reflective mask blank of the present invention is suitable as a reflective mask used for EUV exposure.

### EXAMPLES

The present invention will now be described in further detail with reference to the following Examples.

The materials, amounts used, ratios, treatment details, treatment procedures and the like described in the following Examples can be appropriately modified without departing from the scope of the present invention. Hence, the scope of the present invention should not be construed as being limited to the following Examples.

Here, Ex. 1 to 4 correspond to Examples of the present invention; and Ex. 5 corresponds to Comparative Example.

### <Ex. 1>

A method for producing a reflective mask blank of Ex. 1 will be described in detail below as a representative example.

### [Substrate]

First, a SiO₂—TiO₂ glass substrate (outer dimensions: 6 inches (152 mm) square, thickness: 6.3 mm) was prepared as the substrate. This glass substrate had a thermal expansion coefficient of 0.02×10⁻⁷/° C. at 20° C., a Young's modulus of 67 GPa, a Poisson's ratio of 0.17 and a specific stiffness of 3.07×10⁷ m²/s². The first main surface of the substrate had a quality assurance area polished to a root mean square roughness (Rq) of 0.15 nm or less and a flatness of 100 nm or less. A Cr film with a thickness of 100 nm was deposited on the second main surface of the substrate by magnetron sputtering. The sheet resistance of the Cr film was 100 Q/sq.

### [Multilayer Reflective Film]

As the multilayer reflective film, a Mo/Si multilayer reflective film was formed on the first main surface of the substrate. The Mo/Si multilayer reflective film was obtained by repeating 40 cycles of depositing a Si film (film thickness: 4.5 nm) and a Mo film (film thickness: 2.3 nm) by ion beam sputtering, and after the deposition of the 40th Mo film, additionally depositing a Si film (film thickness: 4.5 nm). The total thickness of the Mo/Si multilayer reflective film was 276.5 nm ((4.5 nm+2.3 nm)×40+4.5 nm).

### [Protective Film]

As the protective film, a Ru film (film thickness: 0.9 nm) was deposited on the multilayer reflective film by ion beam sputtering, followed by deposition of a Rh film (film thickness: 1.6 nm) on the Ru film by ion beam sputtering.

### [Phase Shift Film]

Using a multi-target magnetron sputtering apparatus, a PtTaW film (phase shift film) was deposited on the protective film. The deposition conditions for formation of the PtTaW film were as follows.
Targets: Pt target, Ta target and W target
Sputtering gas: Ar gas
Sputtering pressure: 0.3 Pa
Applied power: 12 to 120 W
Sputtering rate: 0.3 nm/sec
Film thickness: 30 nm

Each target was sputtered using a DC power supply. The power applied to each target was adjusted to achieve the film composition shown in the table below.

### Ex. 2 to Ex. 4

A reflective mask blank of each Ex. was obtained in the same manner as in Ex. 1, except that a phase shift film (Ex. 2 to Ex. 4) having the film composition shown in the table below was formed by adjusting the target types and the applied power.

### Ex. 5

A reflective mask blank of this example was obtained in the same manner as in Ex. 1, except that a phase shift film (Ex. 5) consisting solely of Pt was formed by applying power only to a Pt target.

### <Measurements>

### [XPS]

The deposited phase shift film was analyzed by XPS according to the method described above. The composition of the phase shift film and the chemical shift of each element are shown in the table below.

Here, the chemical shifts of the respective elements were calculated from the peak values corresponding to the following orbitals. The binding energy peak values used as references are indicated in parentheses.
Hf: Hf 4f_{7/2} peak (14.3 eV)
Ta: Ta 4f_{7/2} peak (21.8 eV)
W: W 4f_{7/2} peak (31.5 eV)

### [Optical Properties]

The optical properties of the deposited phase shift film were measured by the methods described above. The refractive index n for EUV light and the extinction coefficient k are shown in the table below.

### [Crystallite Size]

The crystallite size of the deposited phase shift film was determined by the method described above. The results are shown in the table below.

In order to exclude the influence of overlapping diffraction lines from the Mo layers of the multilayer reflective film on the crystallinity evaluation, the crystallite size of the deposited phase shift film of each Ex. was determined using a sample prepared by depositing a phase shift film on a Si wafer under the same conditions as described above. The crystallite size of the phase shift film deposited on the Si wafer corresponds well to the crystallite size of the phase shift film in the reflective mask blank obtained by the above procedure.

For practical use, the crystallite size is preferably 10 nm or smaller, more preferably 6.0 nm or smaller, still more preferably 4.0 nm or smaller.

### [SPM Resistance]

The SPM resistance of the deposited phase shift film in the reflective mask blank was evaluated by the following method.

First, the phase shift film was subjected to etching by contact with SPM (75 vol % concentrated sulfuric acid and 25 vol % hydrogen peroxide) at 100° C. for 20 minutes. After the etching, the film thickness of the phase shift film was measured by XRR.

The XRR measurement was conducted using Smart Lab HTP manufactured by Rigaku Corporation. As the X-ray source, CuKα radiation was used. The tube voltage was set to 40 kV, and the tube current was set to 30 mA. The analysis was conducted using the accompanying software (GlobalFit).

In the table below, the change in film thickness before and after the etching is shown, where a negative value indicates a decrease in film thickness of the phase shift film.

The absolute value of the change in film thickness before and after the etching is preferably 1.0 nm or less, more preferably 0.5 nm or less, still more preferably 0.2 nm.

### <Results>

The composition of the phase shift film in the reflective mask blank of each Ex. and the measurement results are shown in the table below.

TABLE 1

| | | | | | | | | | | | | SPM |
|---|---|---|---|---|---|---|---|---|---|---|---|---|
| | | | | | | | | | | | | Resistance |
| | | | | | | | | | | | | (Film |
| | | | | | Optical | | Chemical Shift | | | | Crystallite | Thickness |
| Table | Composition [atomic %] | | | | Properties | | Pt | Hf | Ta | W | Size | Change) |
| 1 | Pt | Hf | Ta | W | n | k | [eV] | [eV] | [eV] | [eV] | [nm] | [nm] |
| Ex. 1 | 53.2 | — | 34.8 | 12.0 | 0.914 | 0.045 | 0.9 | — | 1.1 | −0.4 | 3.3 | 0.0 |
| Ex. 2 | 55.4 | — | 44.6 | — | 0.915 | 0.045 | 0.9 | — | 1.1 | — | 3.2 | 0.1 |
| Ex. 3 | 61.2 | 21 | — | 17.5 | 0.915 | 0.045 | 0.5 | 0.8 | — | −0.3 | 3.3 | −0.5 |
| Ex. 4 | 63.6 | 36 | — | — | 0.922 | 0.043 | 0.7 | 0.8 | — | — | 3.2 | −0.9 |
| Ex. 5 | 100.0 | — | — | — | 0.890 | 0.060 | 0.0 | — | — | — | 12.0 | 0.0 |

It is apparent from the results of Ex. 1 to Ex. 4 shown in Table 1 that the phase shift film containing Pt and the first element X1, in which the content of the first element X1 relative to all atoms in the phase shift film is 10 atomic % or more and less than 70.0 atomic % and, in XPS analysis of the phase shift film, the chemical shift of the peak corresponding to the Pt 4f_{7/2} orbital is 0.3 eV or more, exhibits a small crystallite size and thus low crystallinity.

On the other hand, it is apparent from the result of Ex. 5 that a phase shift film consisting only of Pt does not exhibit low crystallinity.

As is apparent from comparison of Ex. 1 and Ex. 2 with Ex. 3 and Ex. 4, the phase shift film shows excellent SPM resistance when the first element X1 includes at least Ta and the content of Ta relative to all atoms in the phase shift film is 10.0 atomic % or more and less than 70.0 atomic %.

This application is a continuation of PCT Application No. PCT/JP2024/036843, filed on Oct. 16, 2024, which is based upon and claims the benefit of priority from Japanese Patent Application No. 2023-199954 filed on Nov. 27, 2023. The contents of those applications are incorporated herein by reference in their entireties.

### REFERENCE SYMBOLS

10: Reflective mask blank
12: Substrate
14: Multilayer reflective film
16: Protective film
18: Phase shift film
18pt: Phase shift film pattern
22: Conductive film
40, 42: Resist pattern

What is claimed is:

1. A reflective mask blank comprising, in the following order:
a substrate;
a multilayer reflective film configured to reflect EUV light;
a protective film; and
a phase shift film configured to cause a phase shift in EUV light, wherein the phase shift film comprises:
Pt; and
at least one first element X1 selected from the group consisting of Cr, Hf, Ta and W,
wherein the content of the first element X1 in the phase shift film is 10.0 atomic % or more and less than 70.0 atomic % relative to all atoms in the phase shift film, and
wherein the phase shift film, when analyzed by X-ray photoelectron spectroscopy, shows a peak corresponding to a Pt 4f_{7/2} orbital, the peak having a chemical shift of 0.3 eV or more.

2. The reflective mask blank according to claim 1, wherein the content of Pt in the phase shift film is 30.0 atomic % or more and less than 90.0 atomic % relative to all atoms in the phase shift film.

3. The reflective mask blank according to claim 1,
wherein the first element X1 includes at least Ta, and
wherein the content of Ta in the phase shift film is 10.0 atomic % or more and less than 70.0 atomic % relative to all atoms in the phase shift film.

4. The reflective mask blank according to claim 1,
wherein the first element X1 includes at least W, and
wherein the content of W in the phase shift film is 10.0 to 40.0 atomic % relative to all atoms in the phase shift film.

5. The reflective mask blank according to claim 1,
wherein the first element X1 includes at least Hf, and
wherein the content of Hf in the phase shift film is 10.0 to 60.0 atomic % relative to all atoms in the phase shift film.

6. The reflective mask blank according to claim 1, wherein the phase shift film has a refractive index n of 0.910 or higher.

7. The reflective mask blank according to claim 1, wherein the phase shift film has an extinction coefficient of lower than 0.050.

8. The reflective mask blank according to claim 1, wherein the phase shift film is amorphous.

9. The reflective mask blank according to claim 1, wherein the phase shift film has a film thickness of 10 to 60 nm.

10. The reflective mask blank according to claim 1, wherein the protective film comprises at least one element selected from the group consisting of Si, Y, Ru, Rh, Pd and Al.

11. The reflective mask blank according to claim 1, further comprising an etching mask film, different from the phase shift film, on a side of the phase shift film opposite to the substrate,
wherein the etching mask film comprises at least one element selected from the group consisting of Al, Si, Ti, Cr, Y, Nb, Mo, Ta and Hf.

12. The reflective mask blank according to claim 11, wherein the etching mask film further comprises at least one element selected from the group consisting of B, C, N, O and F.

13. A reflective mask comprising a phase shift film pattern formed by patterning the phase shift film of the reflective mask blank according to claim 1.

14. A method for producing a reflective mask, comprising: patterning the phase shift film of the reflective mask blank according to claim 1.
